(19) United States
(12) Patent Application Publication
(10) Pub. No.: US 2026/0089983 A1
(43) Pub. Date: Mar. 26, 2026

(54) INDUCTORS MANUFACTURED USING DEEP TRENCH ISOLATION

(71) Applicant: Microchip Technology Incorporated, Chandler, AZ (US)

(72) Inventors: Mazhar Hoque, Gilbert, AZ (US); Amit Rai, Chandler, AZ (US); Samir Fuke, Tempe, AZ (US); Joseph Rascon, Chandler, AZ (US); Randy Yach, Phoenix, AZ (US)

(73) Assignee: Microchip Technology Incorporated, Chandler, AZ (US)

(21) Appl. No.: 18/959,767

(22) Filed: Nov. 26, 2024

Related U.S. Application Data
(60) Provisional application No. 63/698,973, filed on Sep. 25, 2024.
(60) Provisional application No. 63/698,968, filed on Sep. 25, 2024.
(60) Provisional application No. 63/698,986, filed on Sep. 25, 2024.

(51) Int. Cl. H01L 27/06; H01L 29/93

(52) U.S. Cl. CPC H10D 1/20; H10D 1/64; H10D 84/60

(57) ABSTRACT

An apparatus, system, and method for the manufacturing of an inductor using deep trench isolation (DTI) is disclosed. The apparatus may include a doped substrate forming a well. The apparatus may also include a trench etched in the substrate. The trench may have a shape of a coil. The apparatus may additionally include a dielectric in the trench. The apparatus may further include a conductor within the dielectric in the trench. The dielectric and the conductor may create a first inductor.

### PRIORITY

This application claims priority to U.S. Provisional Patent Application Nos. 63/698,968; 63/698,973; and 63/698,986 filed Sep. 25, 2024, the contents of which are hereby incorporated in their entirety.

### TECHNICAL FIELD

The present disclosure relates to varactors, and in particular, to the manufacturing of varactors and inductors using deep trench isolation.

### BACKGROUND

A varactor is a type of semiconductor device whose capacitance varies with the applied reverse voltage. The capacitance of the varactor results from the depletion region in the p-n junction changing size as the reverse voltage changes. Varactors are found in voltage-controlled oscillators (VCOs), LC tank circuits, frequency multipliers, and tunable filters. Varactors using a metal oxide semiconductor field effect transistor (MOSFET) typically have a large footprint on an integrated circuit (IC) because the capacitor area is defined by the transistor gate area.

Inductors on silicon substrates may be used in an integrated circuit (IC). The most common type of inductor is a planar inductor. A planar inductor is a spiral pattern of metal conductors on the surface of the silicon substrate. The inductance of the inductor is determined by the number of turns, the area enclosed by the spiral, and the thickness of the metal layer. Increasing the inductance of the inductor requires increasing the footprint of the inductor on the silicon substrate.

Deep Trench Isolation (DTI) is a semiconductor manufacturing process used to create highly isolated regions within ICs. DTI involves etching deep trenches into the silicon wafer, filling the trench with an insulating material, and then planarizing the surface. DTI allows for the creation of smaller, more densely packed transistors, increasing the number of devices that can be integrated onto a single chip. DTI is used to create high voltage power devices in Bipolar Complementary Metal-Oxide-Semiconductor (CMOS) Double-Diffused Metal-Oxide-Semiconductor (DMOS) (BCD) technology.

### SUMMARY OF THE INVENTION

Aspects provide systems and methods for the manufacturing of an inductor using deep trench isolation. Examples of the present disclosure may include an apparatus. The apparatus may include a substrate doped to form a well. The apparatus may also include a trench etched in the substrate. The trench may have a shape of a coil. The apparatus may additionally include a dielectric in the trench. The apparatus may further include a conductor within the dielectric in the trench. The dielectric and the conductor may create a first inductor.

In combination with any of the above examples, the conductor may be at least one of a polysilicon or a metal.

In combination with any of the above examples, the apparatus may further include an inductor coil vertically stacked above a surface of the substrate. The first inductor may be tied to the inductor coil to form a combined inductor.

In combination with any of the above examples, the apparatus may further include an inductor coil vertically stacked above a surface of the substrate and forming a second inductor. The second inductor may be a primary coil of a transformer and the first inductor may be a secondary coil of the transformer.

In combination with any of the above examples, the apparatus may further include a capacitor vertically stacked above a surface of the substrate and a conductive layer between the surface of the substrate and the capacitor.

In combination with any of the above examples, the capacitor may be a finger metal-oxide-metal (FMOM) capacitor or a metal-insulator-metal (MIM) capacitor.

In combination with any of the above examples, the apparatus may further include a silicon base and an insulator layered on the silicon base. The substrate may be layered on the insulator.

Alone or in combination with any of the above examples, examples of the present disclosure may include a method. The method may include etching a trench in a substrate. The trench may have a coil shape and the substrate may be doped to form a well. The method may also include filling the trench with a dielectric and placing a conductor within the dielectric. The dielectric and the conductor may create a first inductor.

In combination with any of the above examples, the conductor may be at least one of a polysilicon or a metal.

In combination with any of the above examples, the method may further include stacking an inductor coil vertically above a surface of the substrate. The first inductor may be tied to the inductor coil to form a combined inductor.

In combination with any of the above examples, the method may further include stacking an inductor coil vertically above a surface of the substrate to form a second inductor. The second inductor may be a primary coil of a transformer and the first inductor is a secondary coil of the transformer.

In combination with any of the above examples, the method may further include stacking a capacitor vertically above a surface of the substrate and placing a conductive layer between the surface of the substrate and the capacitor.

In combination with any of the above examples, the capacitor may be a finger metal-oxide-metal (FMOM) capacitor or a metal-insulator-metal (MIM) capacitor.

In combination with any of the above examples, the method may further include layering the substrate on an insulator and layering the insulator on a silicon base.

Alone or in combination with any of the above examples, examples of the present disclosure may include an inductor made by a process. The process may include etching a trench in a substrate. The trench may have a coil shape and the substrate may be doped to form a well. The process may also include filling the trench with a dielectric and placing a conductor within the dielectric. The dielectric and the conductor may create a first inductor.

In combination with any of the above examples, the conductor may be at least one of a polysilicon or a metal.

In combination with any of the above examples, the inductor may be made of the process including stacking an inductor coil vertically above a surface of the substrate. The inductor may be tied to the inductor coil to form a combined inductor.

In combination with any of the above examples, the inductor may be made of the process including stacking an inductor coil vertically above a surface of the substrate to form a second inductor. The second inductor may be a primary coil of a transformer and the first inductor is a secondary coil of the transformer.

In combination with any of the above examples, the first inductor may be made of the process including stacking a capacitor vertically above a surface of the substrate and placing a conductive layer between the surface of the substrate and the capacitor.

In combination with any of the above examples, the capacitor may be a finger metal-oxide-metal (FMOM) capacitor or a metal-insulator-metal (MIM) capacitor.

### BRIEF DESCRIPTION OF THE DRAWINGS

The figures illustrate examples of systems and methods for the manufacturing of inductors and varactors using deep trench isolation (DTI).

FIGS. 1A, 1B, and 1C illustrate a top view and cross-sectional views, respectively, of a varactor manufactured using DTI in a well, according to examples of the present disclosure;

FIGS. 2A and 2B illustrate a top view and cross-sectional view, respectively, of a varactor manufactured using DTI in an isolated well, according to examples of the present disclosure;

FIGS. 3A and 3B illustrate a top view and cross-sectional view, respectively, of a high density vertically stacked LC tank with an inductor using metal stack and a varactor manufactured using DTI, according to examples of the present disclosure;

FIGS. 4A and 4B illustrate a top view and cross-sectional view, respectively, of a vertically stacked higher density capacitor with a metal-oxide-metal (MOM) capacitor and a varactor manufactured using DTI, according to examples of the present disclosure;

FIG. 5 illustrates a method performed for manufacturing a varactor using deep trench isolation (DTI), according to examples of the present disclosure;

FIG. 6 illustrates a more detailed method performed for manufacturing a varactor using DTI, according to examples of the present disclosure;

FIGS. 7A, 7B, and 7C illustrate a top view and cross-sectional views, respectively, of an inductor manufactured using DTI, according to examples of the present disclosure;

FIGS. 8A and 8B illustrate a top view and cross-sectional view, respectively, of an inductor formed of an inductor coil in a trench tied to an inductor coil stacked above the substrate, according to examples of the present disclosure;

FIGS. 9A and 9B illustrate a top view and cross-sectional view, respectively, of a high density vertically stacked LC tank with an inductor manufactured using DTI and a capacitor, according to examples of the present disclosure;

FIGS. 10A and 10B illustrate a top view and cross-sectional view, respectively, of a vertically stacked high density transformer manufactured using DTI, according to examples of the present disclosure;

FIG. 11 illustrates a method performed for manufacturing an inductor using DTI, according to examples of the present disclosure;

FIG. 12 illustrates a more detailed method performed for manufacturing an inductor using DTI, according to examples of the present disclosure;

FIGS. 13A, 13B, and 13C illustrate a top view and cross-sectional views, respectively, of an inductor manufactured using DTI, according to examples of the present disclosure;

FIGS. 14A and 14B illustrate a top view and cross-sectional view, respectively, of an inductor manufactured using DTI using an isolated well, according to examples of the present disclosure;

FIG. 15A illustrates a top view and FIGS. 15B, 15C, and 15D illustrate cross-sectional views of the dimensions of a DTI depletion region, according to examples of the present disclosure;

FIG. 16 illustrates a method performed for manufacturing an inductor with depletion regions created using DTI, according to examples of the present disclosure; and

FIG. 17 illustrates a more detailed method performed for manufacturing an inductor with depletion regions created using DTI, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, a method for the manufacturing inductors and varactors using deep trench isolation (DTI) are provided. Manufacturing the varactor using DTI may improve the quality factor of the LC tank circuit. Additionally, a varactor manufactured using DTI may reduce the chip area of the varactor and may improve the symmetry of the circuit. Finally, manufacturing a varactor using DTI may lower the flicker noise up-conversion (phase noise). The varactor manufactured using DTI may be used in radio frequency (RF) circuits with LC tank circuits or voltage-controlled oscillators (VCOs). These RF circuits may be used in a variety of applications including, but not limited to, automotive and industrial applications.

According to an aspect of the invention, a method for the manufacturing an inductor using DTI is provided. The inductor manufactured using DTI may be used in radio frequency (RF) circuits with LC tank circuits, a Balun circuit, or a transformer. These RF circuits may be used in a variety of applications including, but not limited to, automotive and industrial applications.

According to an aspect of the invention, a method for the manufacturing of an inductor with a high quality factor using a biased deep trench is provided. The inductor may include a high resistance depletion region created by biased DTI. The depletion region may increase the effective resistance of the area under the inductor and may reduce losses caused by eddy currents. This loss reduction may result in the inductor having a higher quality factor.

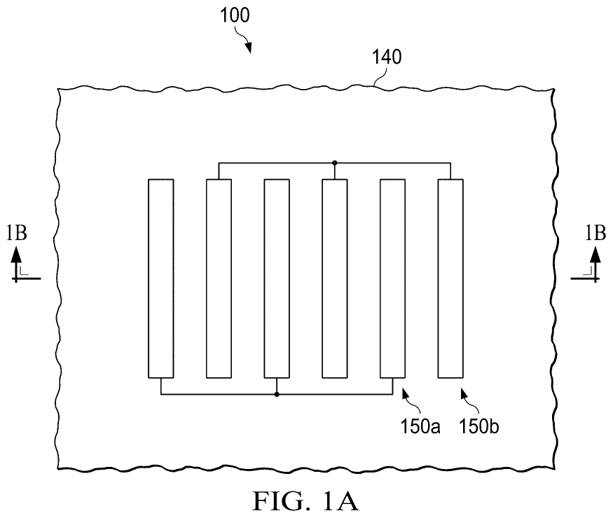

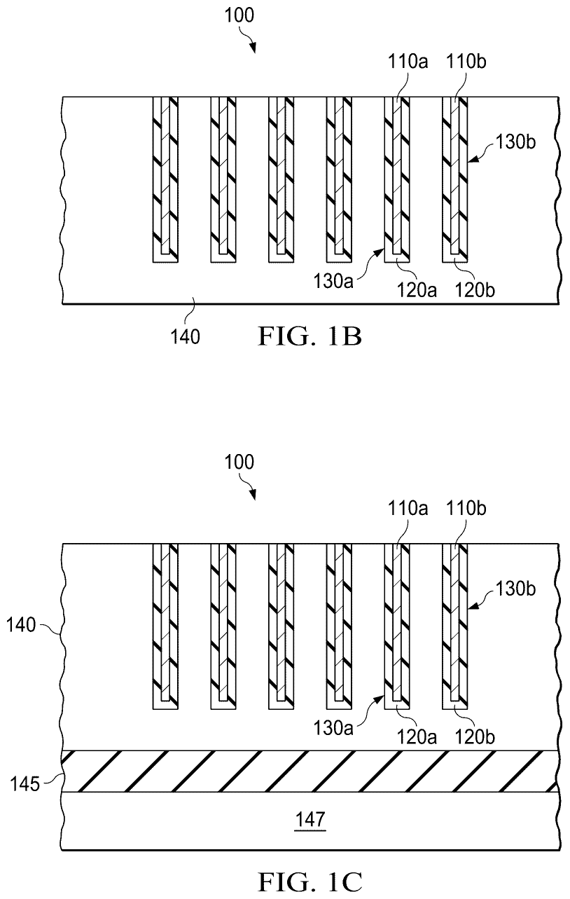

FIGS. 1A, 1B, and 1C illustrate a top view and cross-sectional views, respectively, of a varactor manufactured using DTI in a well, according to examples of the present disclosure. Varactor 100 may be formed with a plurality of varactors formed of conductor 110 and dielectric 120 in trenches 130. For example, trench 130a may be filled with dielectric 120a and conductor 110a. Substrate 140 may act as a bottom electrode and conductor 110a may act as a top electrode such that trench 130a, dielectric 120a, and conductor 110a form varactor 150a. Similarly, trench 130b may be filled with dielectric 120b and conductor 110b. Substrate 140 may act as a bottom electrode and conductor 110b may act as a top electrode such that trench 130b, dielectric 120b, and conductor 110b form varactor 150b.

Conductor 110 may be formed of any suitable conductive material, such as a polysilicon, aluminum, or copper. Dielectric 120 may be formed of any suitable insulating material, such as an oxide (e.g., silicon dioxide) or a nitride (e.g., silicon nitride). Conductor 110 and dielectric 120 may be filled in trench 130 using any suitable technique, such as chemical vapor deposition (CVD) or plasma-enhanced CVD (PECVD).

Trench 130 may have any suitable depth. For example, the depth of trench 130 may be on the order of 10s of μms. Trenches 130 may be etched in substrate 140 in parallel. For example, trench 130a may be etched parallel to trench 130b. Trenches 130 may be etched using any suitable technique, such as deep reactive ion etching (DRIE).

Substrate 140 may be doped such that it forms either a P-well or an N-well. Substrate 140 may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. As shown in FIG. 1C, in some examples, substrate 140 may be layered on insulator 145. Insulator 145 may be formed of any suitable insulating material, such as a buried oxide (e.g., silicon dioxide) or a nitride (e.g., silicon nitride). Insulator 145 may be layered on silicon base 147.

Varactors 150a and 150b may be connected differentially to collectively form varactor 100. The differential connection may improve the quality factor of varactor 100.

The capacitance of varactor 100 may be determined by the surface area of conductor 110. The surface area of conductor 110 may be determined by the depth of trench 130. By increasing the surface area of conductor 110 using the depth of trench 130, the capacitance of varactor 100 may be increased without increasing the footprint of varactor 100 on substrate 140.

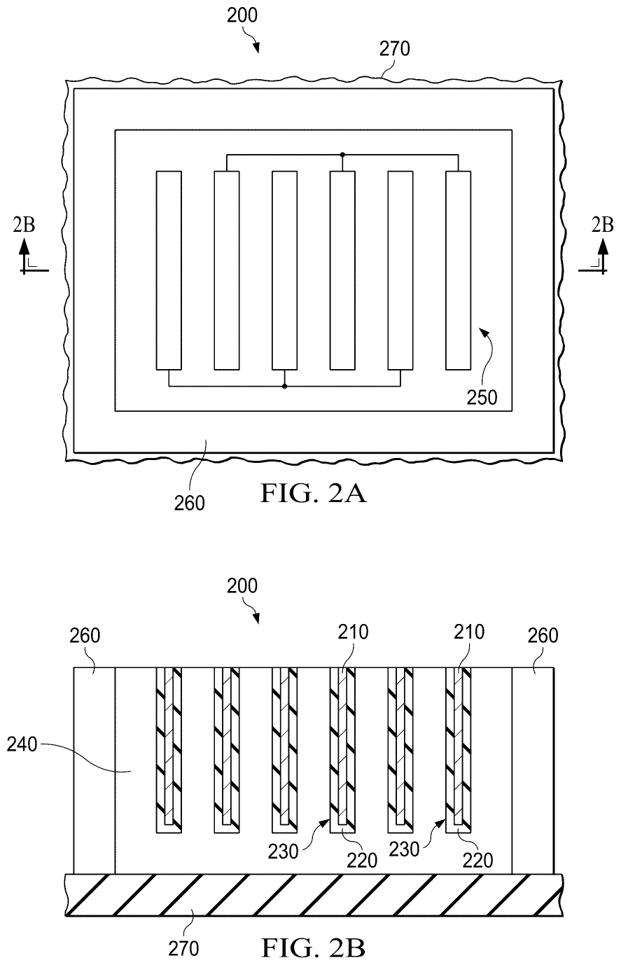

FIGS. 2A and 2B illustrate a top view and cross-sectional view, respectively, of a varactor manufactured using DTI in an isolated well, according to examples of the present disclosure. Varactor 200 may be similar to varactor 100 shown in FIGS. 1A, 1B, and 1C. Similarly, conductor 210, dielectric 220, trench 230, and substrate 240 may be similar to conductor 110, dielectric 120, trench 130, and substrate 140, respectively, shown in FIGS. 1A, 1B, and 1C.

Substrate 240 may be isolated to allow for biasing of the well (either P-well or N-well) formed by substrate 240. Biasing substrate 240 may result in a larger voltage tuning ratio. Substrate 240 may be isolated by surrounding substrate 240 with wells 260 and buried layer 270. Wells 260 and buried layer 270 may have an opposite bias as substrate 240. Specifically, where substrate 240 is a P-well, well 260 may be an N-well and buried layer 270 may be an N-buried layer. Likewise, where substrate 240 is a N-well, well 260 may be a P-well and buried layer 270 may be a P-buried layer.

Varactors 250 may be connected differentially to collectively form varactor 200. The differential connection may improve the quality factor of varactor 200.

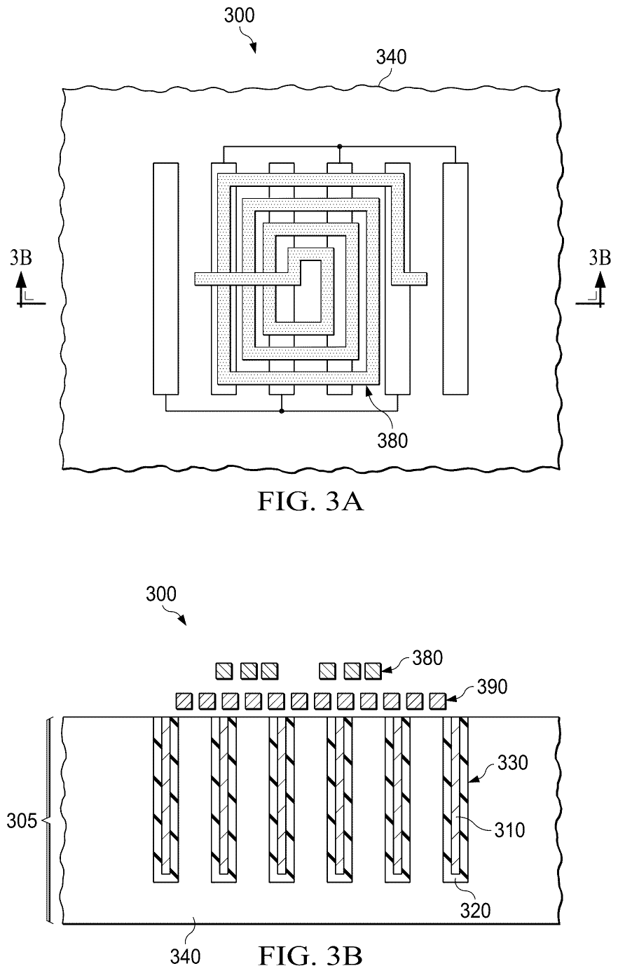

FIGS. 3A and 3B illustrate a top view and cross-sectional view, respectively, of a high density vertically stacked LC tank with an inductor using metal stack and a varactor manufactured using DTI, according to examples of the present disclosure. Varactor 305 may be similar to varactor 100 shown in FIGS. 1A, 1B, and 1C. Similarly, conductor 310, dielectric 320, trench 330, and substrate 340 may be similar to conductor 110, dielectric 120, trench 130, and substrate 140, respectively, shown in FIGS. 1A, 1B, and 1C. While shown in FIG. 3A as a differential varactor, varactor 305 may be made of varactors not connected differentially.

Varactor 305 may be combined with inductor 380 to create LC tank 300. Specifically, inductor 380 may be vertically stacked above varactor 305. Stacking inductor 380 above varactor 305 may reduce the footprint of the LC tank on substrate 340. Inductor 380 may be formed of metal stacks inside the inter layer dielectric above substrate 340.

Conductive layer 390 may be used to isolate inductor 380 from varactor 305. Conductive layer 390 may be biased at ground potential and act as a ground shield to reduce interference between inductor 380 and varactor 305. Conductive layer 390 may be formed of any suitable conductive material, such as a polysilicon or metal layer. Conductive layer 390 may increase the quality factor of inductor 380 by preventing the electric field from reaching substrate 340. Without conductive layer 390, the electric field may generate eddy current loss and degrade the performance of inductor 380.

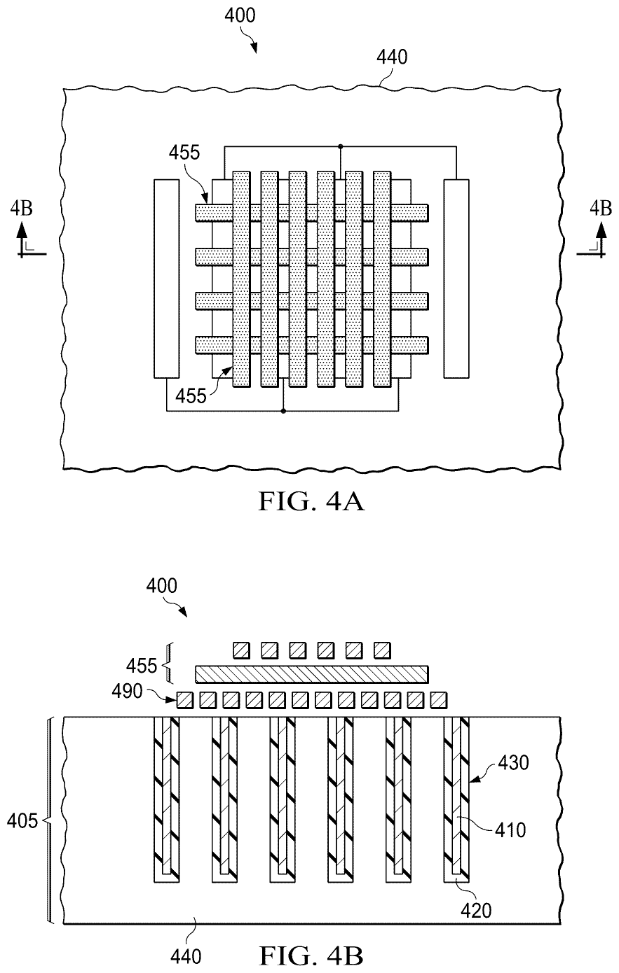

FIGS. 4A and 4B illustrate a top view and cross-sectional view, respectively, of a vertically stacked higher density capacitor with a metal-oxide-metal (MOM) capacitor and a varactor manufactured using DTI, according to examples of the present disclosure. Varactor 405 may be similar to varactor 100 shown in FIGS. 1A, 1B, and 1C. Similarly, conductor 410, dielectric 420, trench 430, and substrate 440 may be similar to conductor 110, dielectric 120, trench 130, and substrate 140, respectively, shown in FIGS. 1A, 1B, and 1C. While shown in FIG. 4A as a differential varactor, varactor 405 may be made of varactors not connected differentially.

Vertically stacked higher density capacitor 400 may be formed of capacitor 455 vertically stacked above varactor 405. Capacitor 455 may be a MOM capacitor or a MIM capacitor. The addition of capacitor 455 to varactor 405 may result in a high-density capacitor with a smaller footprint on substrate 440.

Conductive layer 490 may be used to isolate capacitor 455 from varactor 405. Conductive layer 490 may be biased at ground potential and act as a ground shield to reduce interference between capacitor 455 and varactor 405. Conductive layer 490 may be formed of any suitable conductive material, such as a polysilicon or metal layer. Conductive layer 490 may reduce the coupling between capacitor 455 and varactor 405.

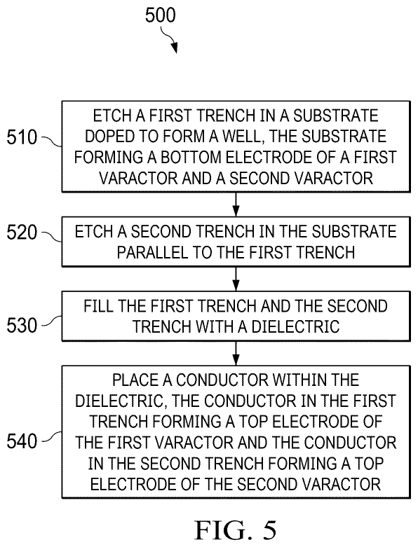

FIG. 5 illustrates a method performed for manufacturing a varactor using DTI, according to examples of the present disclosure. Method 500 may be implemented using any suitable semiconductor manufacturing device designed to perform the functions disclosed herein or any other system operable to implement method 500. Although examples have been described above, other variations and examples may be made from this disclosure without departing from the spirit and scope of these disclosed examples.

Method 500 may begin at block 510 where a first trench may be etched in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The substrate may form a bottom electrode of a varactor. The trench may have a depth on the order of 10s of μms. The trench may be etched using any suitable technique, such as DRIE.

At block 520, a second trench may be etched in the substrate parallel to the first trench. The second trench may be similar to the first trench and have a depth on the order of 10s of μms and be etched using any suitable technique, such as DRIE.

At block 530, the first trench and the second trench may be filled with a dielectric. The dielectric may be formed of any suitable insulating material, such as an oxide (e.g., silicon dioxide) or a nitride (e.g., silicon nitride). The dielectric may be filled in the first trench and the second trench using any suitable technique, such as CVD or PECVD.

At block 540, a conductor may be placed with in the dielectric in the first trench and the second trench. The conductor may be formed of any suitable conductive material, such as a polysilicon, aluminum, or copper. The conductor may be filled in the dielectric in the first trench and the second trench using any suitable technique, such as CVD or PECVD. The conductor in the first trench may form a top electrode of the first varactor and the conductor in the second trench may form a top electrode of the second varactor.

Although FIG. 5 discloses a particular number of operations related to method 500, method 500 may be executed with greater or fewer operations than those depicted in FIG. 5. In addition, although FIG. 5 discloses a certain order of operations to be taken with respect to method 500, the operations comprising method 500 may be completed in any suitable order.

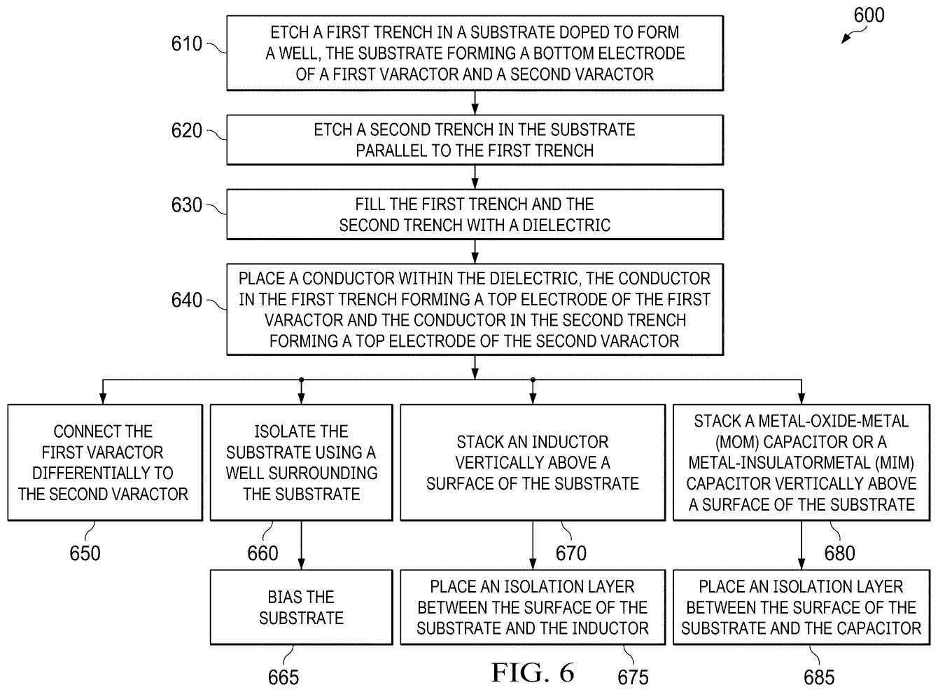

FIG. 6 illustrates a more detailed method performed for manufacturing a varactor using DTI, according to examples of the present disclosure. Method 600 may be implemented using any suitable semiconductor manufacturing device designed to perform the functions disclosed herein or any other system operable to implement method 600. Although examples have been described above, other variations and examples may be made from this disclosure without departing from the spirit and scope of these disclosed examples.

Method 600 may begin at block 610 where a first trench may be etched in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The substrate may form a bottom electrode of a varactor. The trench may have a depth on the order of 10s of μms. The trench may be etched using any suitable technique, such as DRIE.

At block 620, a second trench may be etched in the substrate parallel to the first trench. The second trench may be similar to the first trench and have a depth on the order of 10s of μms and be etched using any suitable technique, such as DRIE.

At block 630, the first trench and the second trench may be filled with a dielectric. The dielectric may be formed of any suitable insulating material, such as an oxide (e.g., silicon dioxide) or a nitride (e.g., silicon nitride). The dielectric may be filled in the first trench and the second trench using any suitable technique, such as CVD or PECVD.

At block 640, a conductor may be placed with in the dielectric in the first trench and the second trench. The conductor may be formed of any suitable conductive material, such as a polysilicon, aluminum, or copper. The conductor may be filled in the dielectric in the first trench and the second trench using any suitable technique, such as CVD or PECVD. The conductor in the first trench may form a top electrode of the first varactor and the conductor in the second trench may form a top electrode of the second varactor.

At block 650, the first varactor and the second varactor may be connected differentially. The differential connection of the first varactor and the second varactor may improve the quality factor of the combined varactor.

At block 660, the substrate may be isolated using a well surrounding the substrate. The substrate may be isolated to allow for biasing of the well (either P-well or N-well) formed by the substrate. Biasing the substrate may result in a larger voltage tuning ratio. The substrate may be isolated by surrounding the substrate with wells and a buried layer. Wells and the buried layer may have an opposite bias as the substrate. Specifically, where the substrate is a P-well, the well may be an N-well and the buried layer may be an N-buried layer. Likewise, where the substrate is a N-well, the well may be a P-well and the buried layer may be a P-buried layer.

At block 665, the substrate may be biased. The substrate may be a P-well or an N-well.

At block 670, an inductor may be stacked vertically above a surface of the substrate. The inductor and first and second varactors may form an LC tank. Stacking the inductor above the first and second varactors may reduce the footprint of the LC tank on the substrate. The inductor may be formed of metal stacks inside the inter layer dielectric above the substrate.

At block 675, a conductive layer may be placed between the surface of the substrate and the inductor. The conductive layer may isolate the inductor from the first and second varactors and may be formed of any suitable conductive material, such as a polysilicon or metal layer. The conductive layer may increase the quality factor of the inductor by preventing the electric field from reaching the substrate. Without the conductive layer, the electric field may generate eddy current loss and degrade the performance of the inductor.

At block 680, a capacitor may be vertically stacked above a surface of the substrate. The capacitor may be a MOM or MIM capacitor. The addition of the MOM or MIM capacitor to the first and second varactors may result in a high-density capacitor with a smaller footprint on the substrate.

At block 685, a conductive layer may be placed between the surface of the substrate and the MOM or MIM capacitor. The conductive layer may isolate the MOM or MIM capacitor from the first and second varactors and may be formed of any suitable conductive material, such as a polysilicon or metal layer. The conductive layer may reduce the coupling between the MOM or MIM capacitor and the first and second varactors.

Although FIG. 6 discloses a particular number of operations related to method 600, method 600 may be executed with greater or fewer operations than those depicted in FIG. 6. In addition, although FIG. 6 discloses a certain order of operations to be taken with respect to method 600, the operations comprising method 600 may be completed in any suitable order.

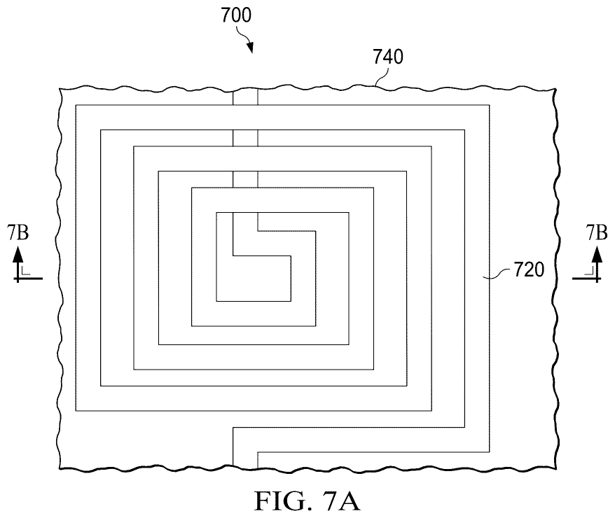

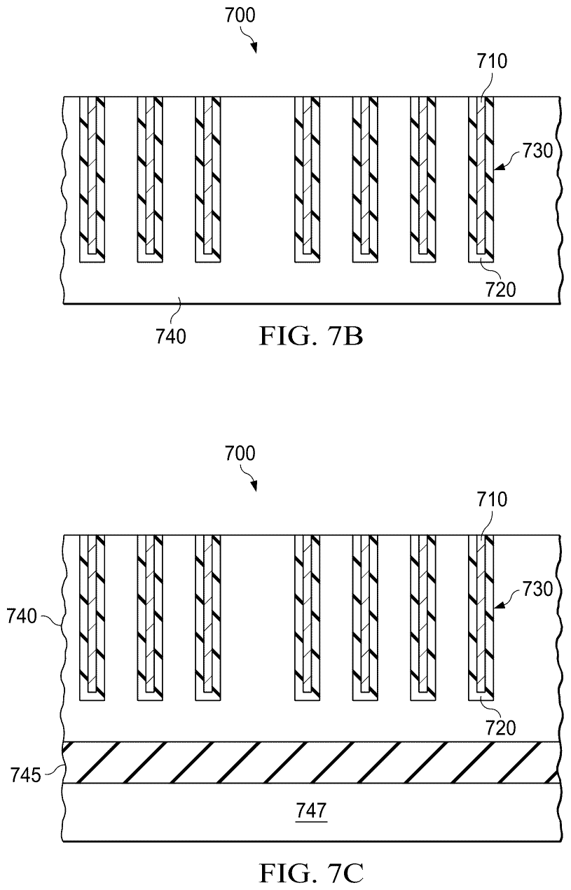

FIGS. 7A, 7B, and 7C illustrate a top view and cross-sectional view, respectively, of an inductor manufactured using DTI, according to examples of the present disclosure. Inductor 700 may be formed of conductor 710 and dielectric 720 in trench 730. Specifically, trench 730 may be etched in a coil pattern and may be filled with dielectric 720 and conductor 710. Conductor 710 and dielectric 720 may be used as inductor track lines to form inductor 700.

Conductor 710 may be formed of any suitable conductive material, such as polysilicon or metal (e.g., aluminum or copper). In some examples, conductor 710 may be replaced with metal inside trench 730. Dielectric 720 may be formed of any suitable insulating material, such as an oxide (e.g., silicon dioxide) or a nitride (e.g., silicon nitride). Conductor 710 and dielectric 720 may be filled in trench 730 using any suitable technique, such as chemical vapor deposition (CVD) or plasma-enhanced CVD (PECVD).

Substrate 740 may be doped such that it forms either a P-well or an N-well. Substrate 740 may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. As shown in FIG. 7C, in some examples, substrate 740 may be layered on insulator 745. Insulator 745 may be formed of any suitable insulating material, such as a buried oxide (e.g., silicon dioxide) or a nitride (e.g., silicon nitride). Insulator 745 may be layered on silicon base 747.

The inductance of inductor 700 may be determined by the surface area of conductor 710. By increasing the surface area of conductor 710 inside trench 730, the inductor track line resistance may be reduced, which may improve the quality factor of inductor 700.

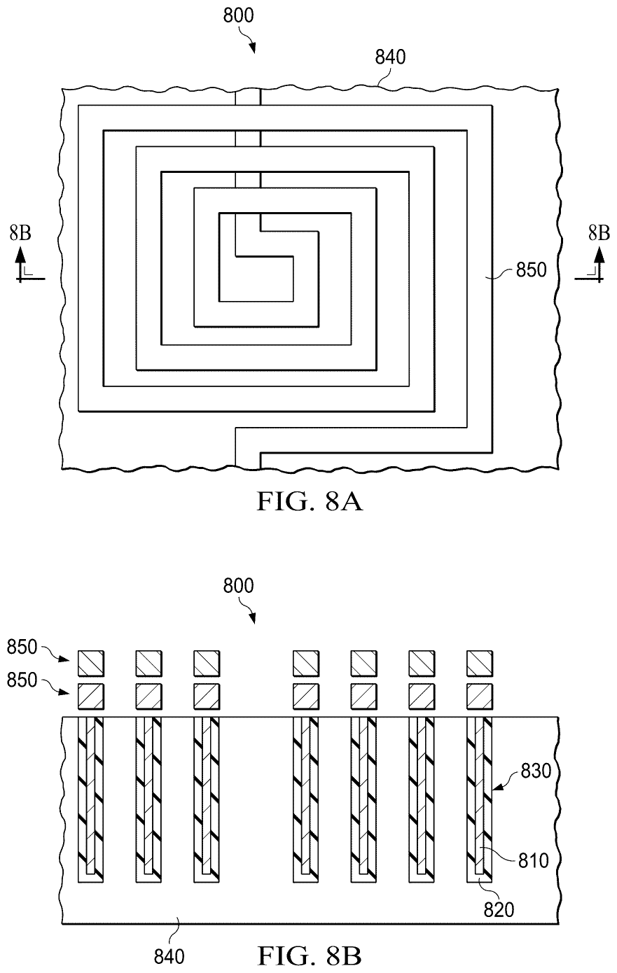

FIGS. 8A and 8B illustrate a top view and cross-sectional view, respectively, of an inductor formed of an inductor coil in a trench tied to an inductor coil stacked above the substrate, according to examples of the present disclosure. Conductor 810, dielectric 820, trench 830, and substrate 840 may be similar to conductor 710, dielectric 720, trench 730, and substrate 740, respectively, shown in FIGS. 7A, 7B, and 7C.

Conductor 810 may be tied to metal stacks 850 in the inter-layer dielectric above substrate 840 to create inductor 800. Tying conductor 810 to metal stacks 850 may reduce track line resistance of inductor 800 and may result in a higher inductor quality factor. Metal stack 850 may be a conventional metal stack used to form an inductor.

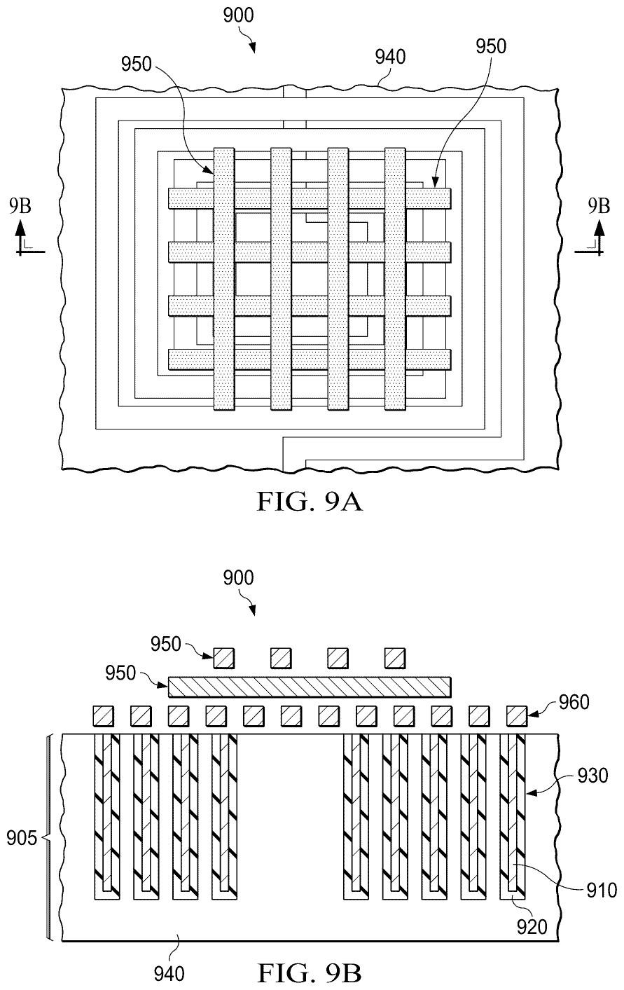

FIGS. 9A and 9B illustrate a top view and cross-sectional view, respectively, of a high density vertically stacked LC tank with an inductor manufactured using DTI and a capacitor, according to examples of the present disclosure. Conductor 910, dielectric 920, trench 930, and substrate 940 may be similar to conductor 710, dielectric 720, trench 730, and substrate 740, respectively, shown in FIGS. 7A, 7B, and 7C. Inductor 905 may be formed of conductor 910 and dielectric 920 in trench 930.

Capacitor 950 may be vertically stacked with inductor 905. Capacitor 950 may be a finger metal-oxide-metal (FMOM) capacitor or metal-insulator-metal (MIM) capacitor created with a metal stack above substrate 940. Vertically stacking capacitor 950 and inductor 905 may result in a smaller footprint for LC tank circuit 900.

Conductive layer 960 may be placed between capacitor 950 and inductor 905 to isolate inductor 905 from capacitor 950. Conductive layer 960 may be biased at ground potential and act as a ground shield to reduce interference between capacitor 950 and inductor 905. Conductive layer 960 may be formed of any suitable conductive material, such as a polysilicon or metal layer. Conductive layer 960 may reduce the coupling between inductor 905 and capacitor 950.

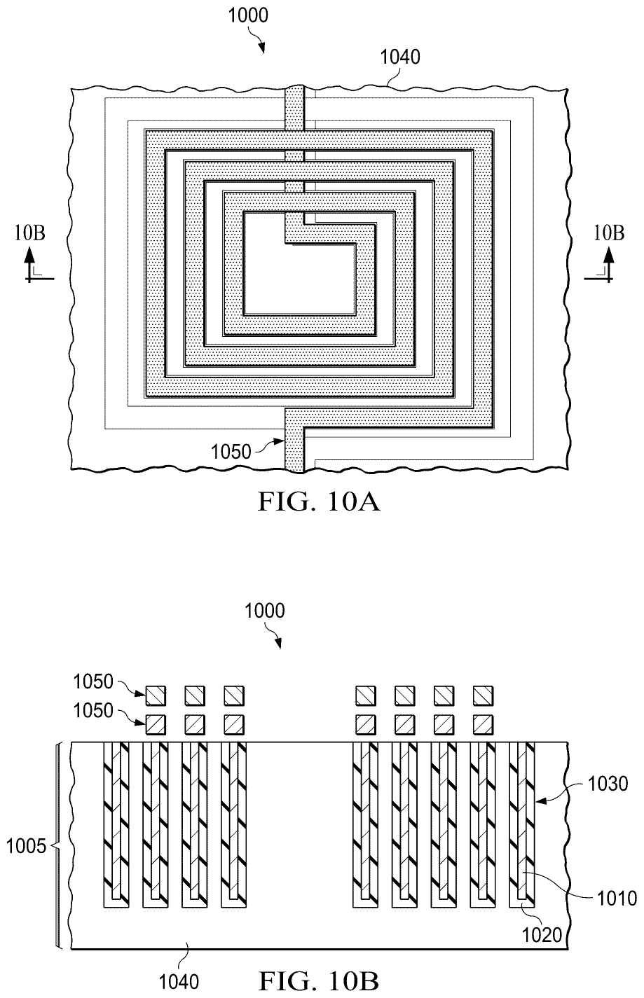

FIGS. 10A and 10B illustrate a top view and cross-sectional view, respectively, of a vertically stacked high density transformer manufactured using DTI, according to examples of the present disclosure. Conductor 1010, dielectric 1020, trench 1030, and substrate 1040 may be similar to conductor 710, dielectric 720, trench 730, and substrate 740, respectively, shown in FIGS. 7A, 7B, and 7C. Inductor 1005 may be formed of conductor 1010 and dielectric 1020 in trench 1030.

Inductor 1005 may be vertically stacked with second inductor 1050. Inductor 1050 may be a primary coil created with a metal stack above substrate 1040 and inductor 1005 may be a secondary coil created with conductor 1010 and dielectric 1020 inside trench 1030. Stacking inductor 1005 and inductor 1050 may create a transformer, such as a Balun or RF transformer, having a smaller footprint on substrate 1040.

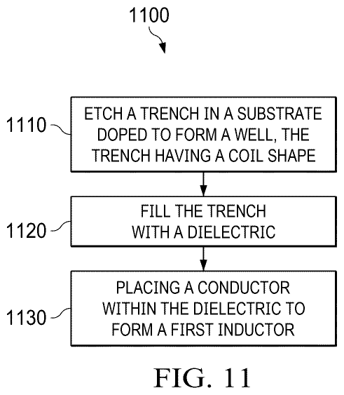

FIG. 11 illustrates a method performed for manufacturing an inductor using DTI, according to examples of the present disclosure. Method 1100 may be implemented using any suitable semiconductor manufacturing device designed to perform the functions disclosed herein or any other system operable to implement method 1100. Although examples have been described above, other variations and examples may be made from this disclosure without departing from the spirit and scope of these disclosed examples.

Method 1100 may begin at block 1110 where a trench may be etched in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The trench may have a depth on the order of 10s of μms. The trench may be etched using any suitable technique, such as DRIE, and may have a coil shape.

At block 1120, the trench may be filled with a dielectric. The dielectric may be formed of any suitable insulating material, such as an oxide (e.g., silicon dioxide) or a nitride (e.g., silicon nitride). The dielectric may be filled in the trench using any suitable technique, such as CVD or PECVD.

At block 1130, a conductor may be placed with in the dielectric in the trench. The conductor may be formed of any suitable conductive material, such as polysilicon or metal (e.g., aluminum or copper). The conductor may be filled in the dielectric in the trench using any suitable technique, such as CVD or PECVD. The conductor in the trench may form a first inductor.

Although FIG. 11 discloses a particular number of operations related to method 1100, method 1100 may be executed with greater or fewer operations than those depicted in FIG. 11. In addition, although FIG. 11 discloses a certain order of operations to be taken with respect to method 1100, the operations comprising method 1100 may be completed in any suitable order.

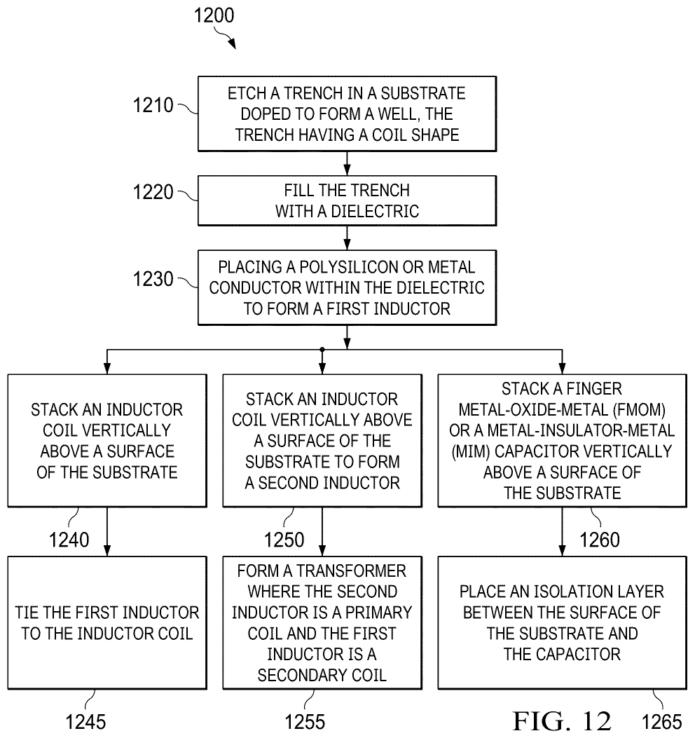

FIG. 12 illustrates a more detailed method performed for manufacturing an inductor using DTI, according to examples of the present disclosure. Method 1200 may be implemented using any suitable semiconductor manufacturing device designed to perform the functions disclosed herein or any other system operable to implement method 1200. Although examples have been described above, other variations and examples may be made from this disclosure without departing from the spirit and scope of these disclosed examples.

Method 1200 may begin at block 1210 where a trench may be etched in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The trench may have a depth on the order of 10s of μms. The trench may be etched using any suitable technique, such as DRIE, and may have a coil shape.

At block 1220, the trench may be filled with a dielectric. The dielectric may be formed of any suitable insulating material, such as an oxide (e.g., silicon dioxide) or a nitride (e.g., silicon nitride). The dielectric may be filled in the trench using any suitable technique, such as CVD or PECVD.

At block 1230, a conductor may be placed with in the dielectric in the trench. The conductor may be formed of any suitable conductive material, such as polysilicon or metal (e.g., aluminum or copper). The conductor may be filled in the dielectric in the trench using any suitable technique, such as CVD or PECVD. The conductor in the trench may form a first inductor.

At block 1240, an inductor coil may be stacked vertically above a surface of the substrate. At block 1245, the first inductor and the inductor coil may be tied together. The first inductor and the inductor coil may form a single inductor. The combined inductor may reduce the track line resistance of the combined inductor and result in a higher inductor quality factor.

At block 1250, an inductor coil may be stacked vertically above a surface of the substrate. The inductor coil may form a second inductor.

At block 1255, a transformer, such as a Balun or RF transformer, may be formed where the second inductor is a primary coil and the first inductor is a secondary coil of the transformer. The transformer may have a smaller footprint on the substrate than a traditional transformer.

At block 1260, a capacitor may be vertically stacked above a surface of the substrate. The capacitor may be a FMOM or MIM capacitor. The addition of the FMOM or MIM capacitor to the first inductor may result in an LC tank circuit with a smaller footprint on the substrate.

At block 1265, a conductive layer may be placed between the surface of the substrate and the FMOM or MIM capacitor. The conductive layer may isolate the first inductor from the FMOM or MIM capacitor and may be formed of any suitable conductive material, such as a polysilicon or metal layer. The conductive layer may reduce coupling between the first inductor and the FMOM or MIM capacitor.

Although FIG. 12 discloses a particular number of operations related to method 1200, method 1200 may be executed with greater or fewer operations than those depicted in FIG. 12. In addition, although FIG. 12 discloses a certain order of operations to be taken with respect to method 1200, the operations comprising method 1200 may be completed in any suitable order.

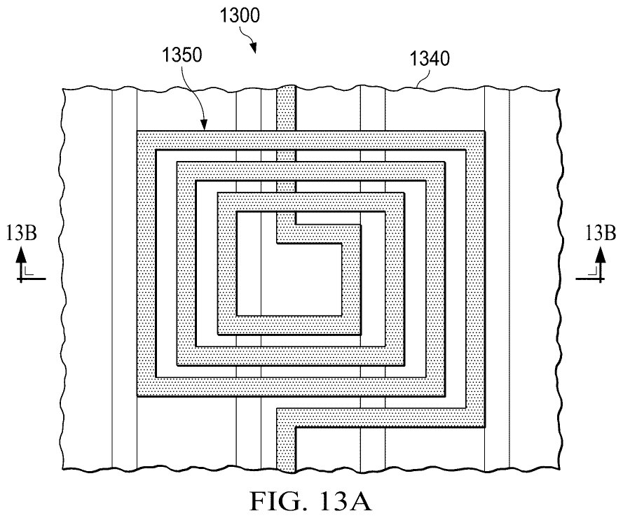

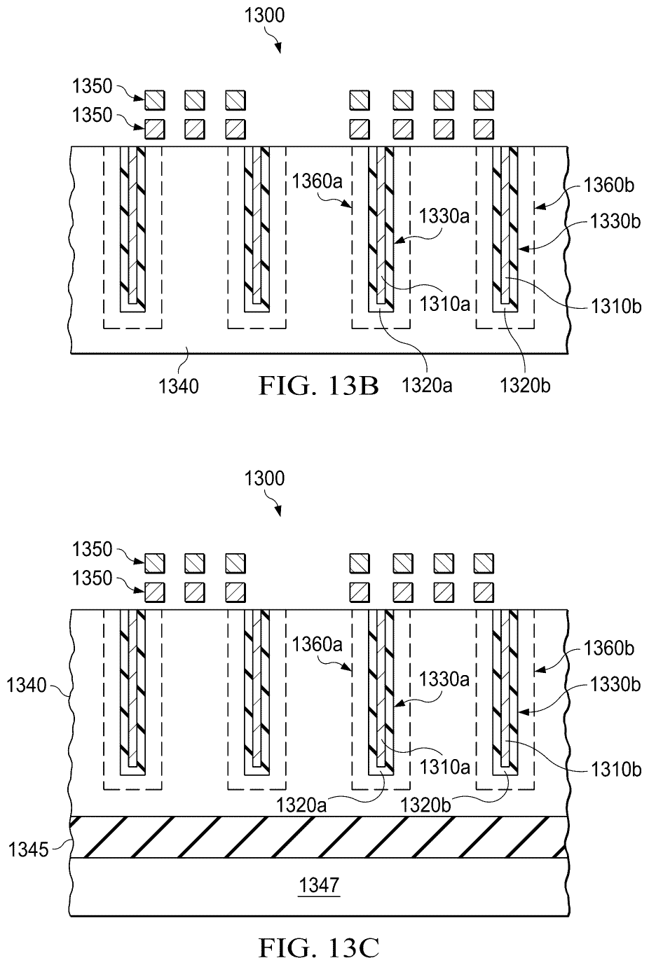

FIGS. 13A, 13B, and 13C illustrate a top view and cross-sectional views, respectively, of an inductor manufactured using DTI, according to examples of the present disclosure. Inductor 1350 may be formed of layered metal stacks arranged in a coil shape. Inductor 1350 may be formed above the surface of substrate 1340. Under inductor 1350 is DTI depletion region 1300. DTI depletion region 1300 may include a plurality of trenches 1330 etched in substrate 1340. Trenches 1330 may be filled with conductor 1310 and dielectric 1320. A given trench 1330, along with conductor 1310 and dielectric 1320, in DTI depletion region 1300 may create DTI depletion region 1360. Trenches 1330 may be spaced such that DTI depletion regions 1360 created by trenches 1330 are as close together as possible without merging. For example, trench 1330a may be spaced from trench 1330b such that DTI depletion region 1360a and DTI depletion region 1360b do not merge.

Conductor 1310 may be formed of any suitable conductive material, such as polysilicon or metal (e.g., aluminum or copper). In some examples, conductor 1310 may be replaced with metal inside trench 1330. Dielectric 1320 may be formed of any suitable insulating material, such as an oxide (e.g., silicon dioxide) or a nitride (e.g., silicon nitride). Conductor 1310 and dielectric 1320 may be filled in trench 1330 using any suitable technique, such as chemical vapor deposition (CVD) or plasma-enhanced CVD (PECVD).

Conductor 1310 may be biased to deplete all p-type carriers (when substrate 1340 is a p-well) or all n-type carriers (when substrate 1340 is an n-well) and increase the effective resistance under inductor 1350. Biasing conductor 1310 may increase the effective resistance of the area of substrate 1340 under inductor 1350, resulting in a reduction of eddy current loss because the DTI depletion regions 1360 have high resistance. The use of the DTI depletion regions may result in inductor 1350 having a higher quality factor.

Substrate 1340 may be doped such that it forms either a P-well or an N-well. Substrate 1340 may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. As shown in FIG. 13C, in some examples, substrate 1340 may be layered on insulator 1345. Insulator 1345 may be formed of any suitable insulating material, such as a buried oxide (e.g., silicon dioxide) or a nitride (e.g., silicon nitride). Insulator 1345 may be layered on silicon base 1347.

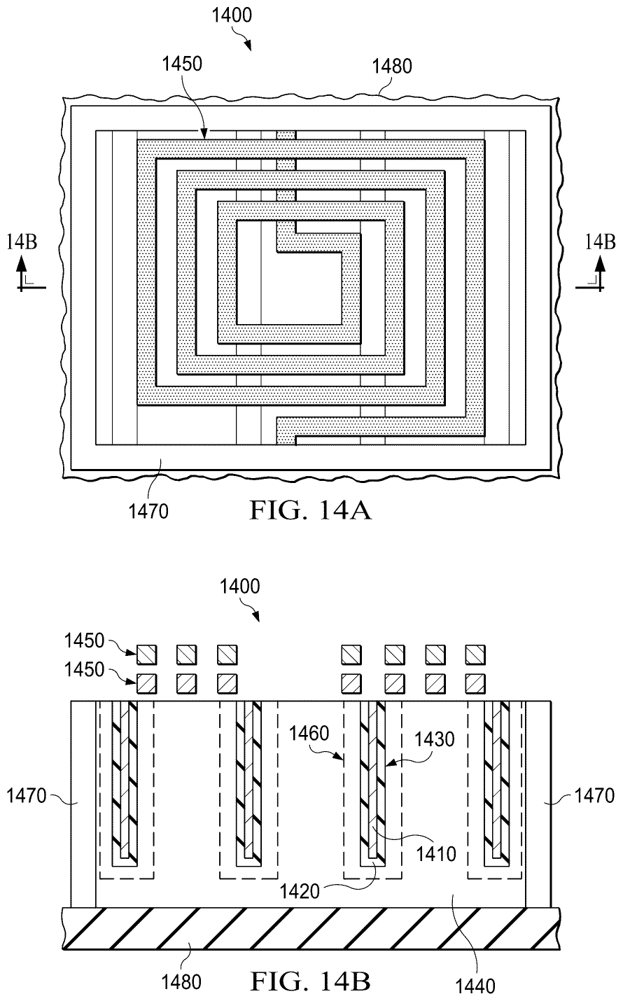

FIGS. 14A and 14B illustrate a top view and cross-sectional view, respectively, of an inductor manufactured using DTI using an isolated well, according to examples of the present disclosure. Conductor 1410, dielectric 1420, trench 1430, substrate 1440, and inductor 1450 may be similar to conductor 1310, dielectric 1320, trench 1330, substrate 1340, and inductor 1350, respectively, shown in FIGS. 13A, 13B, and 13C.

Substrate 1440 may be isolated to allow for biasing of the well (either P-well or N-well) formed by substrate 1440. Biasing substrate 1440 may result in generation of a depletion region under inductor 1450. Biasing conductor 1410, substrate 1440, or both may increase the effective resistance of the area of substrate 4140 under inductor 1450, resulting in a reduction of eddy current loss because the DTI depletion regions 1460 have high resistance. The use of DTI depletion regions 1460 may result in inductor 1450 having a higher quality factor. Substrate 1440 may be isolated by surrounding substrate 1440 with wells 1470 and buried layer 1480. Wells 1470 and buried layer 1480 may have an opposite bias as substrate 1440. Specifically, where substrate 1440 is a P-well, well 1470 may be an N-well and buried layer 1480 may be an N-buried layer. Likewise, where substrate 1440 is a N-well, well 1470 may be a P-well and buried layer 1480 may be a P-buried layer. Isolation of substrate 1440 may be used to protect high sensitivity devices from other interferences caused by other devices within the substrate.

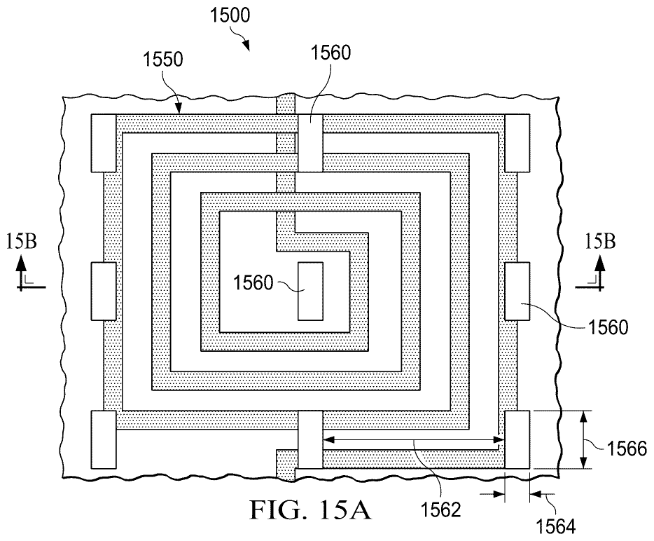

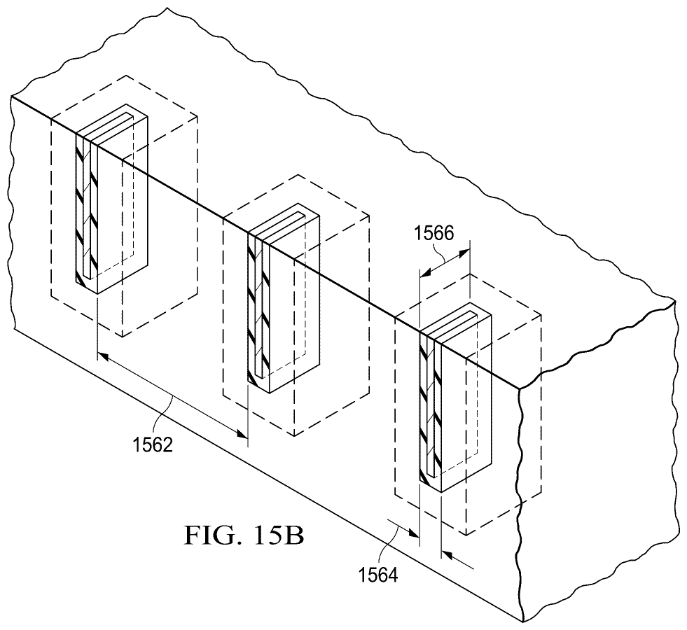

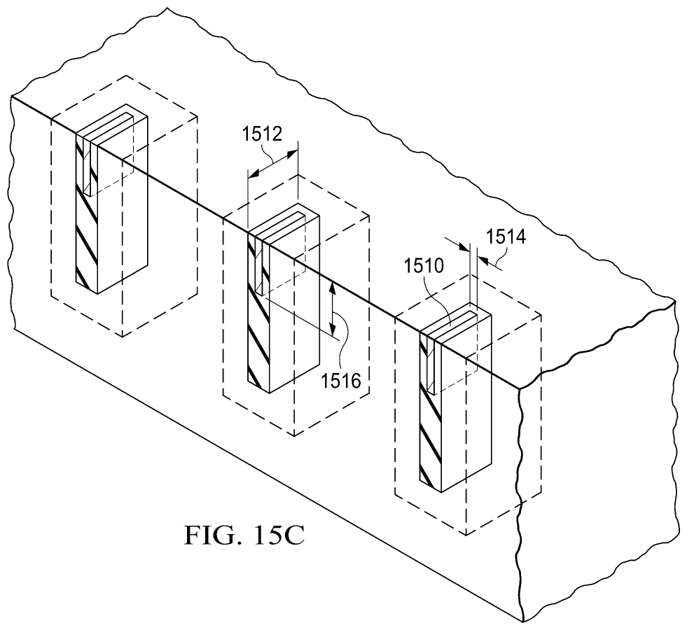

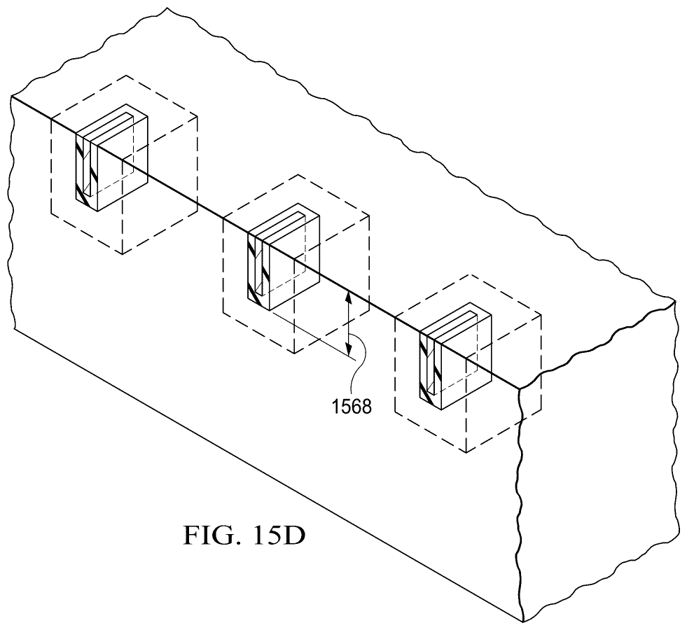

FIG. 15A illustrates a top view and FIGS. 15B, 15C, and 15D illustrate cross-sectional views of the dimensions of a DTI depletion region, according to examples of the present disclosure. DTI depletion regions 1560 may be similar to DTI depletion regions 1300 and 1400 shown in FIGS. 13 and 14, respectively. Conductor 1510 may be similar to conductors 1310 and 1410 shown in FIGS. 13 and 14, respectively.

Spacing 1562, length 1564, width 1566, and depth 1568 of DTI depletion regions 1560 may be varied to improve the quality factor of inductor 1550. The optimization may be based on the intended application of inductor 1550. Additionally, spacing 1562 of DTI depletion regions 1560 may be designed such that the depletion regions created by DTI depletion regions 1560 do not merge.

Additionally, or alternatively, width 1512, length 1514, and depth 1516 of conductor 1510 may be varied to improve the quality factor of inductor 1550. The optimization may be based on the intended application of inductor 1550. For example, depth 1568 of DTI depletion regions 1560 or depth 1516 of conductor 1510 may be adjusted such that DTI depletion regions 1560 are created where eddy currents from inductor 1550 are present.

Spacing 1562, length 1564, width 1566, and depth 1568 of DTI depletion regions 1560 may be improved by tuning with simulation models. Additionally, or alternatively, width 1512, length 1514, and depth 1516 of conductor 1510 may be improved by tuning with simulation models. For example, spacing 1562, length 1564, width 1566, and depth 1568 of DTI depletion regions 1560 may be improved to increase the quality factor of inductor 1550 for a given application.

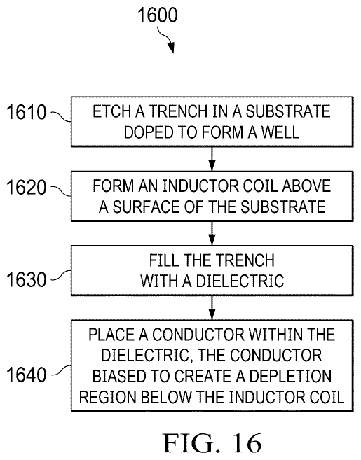

FIG. 16 illustrates a method performed for manufacturing an inductor with depletion regions created using DTI, according to examples of the present disclosure. Method 1600 may be implemented using any suitable semiconductor manufacturing device designed to perform the functions disclosed herein or any other system operable to implement method 1600. Although examples have been described above, other variations and examples may be made from this disclosure without departing from the spirit and scope of these disclosed examples.

Method 1600 may begin at block 1610 where a trench may be etched in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The trench may have a depth on the order of 10s of μms. The trench may be etched using any suitable technique, such as DRIE.

At block 1620, an inductor coil may be formed above a surface of the substrate. The inductor coil may be formed of layered metal stacks arranged in a coil shape.

At block 1630, the trench may be filled with a dielectric. The dielectric may be formed of any suitable insulating material, such as an oxide (e.g., silicon dioxide) or a nitride (e.g., silicon nitride). The dielectric may be filled in the trench using any suitable technique, such as CVD or PECVD.

At block 1640, a conductor may be placed with in the dielectric in the trench. The conductor may be formed of any suitable conductive material, such as polysilicon or metal (e.g., aluminum or copper). The conductor may be filled in the dielectric in the trench using any suitable technique, such as CVD or PECVD. The conductor in the trench may be biased to create a depletion region below the inductor coil.

Although FIG. 16 discloses a particular number of operations related to method 1600, method 1600 may be executed with greater or fewer operations than those depicted in FIG. 16. In addition, although FIG. 16 discloses a certain order of operations to be taken with respect to method 1600, the operations comprising method 1600 may be completed in any suitable order.

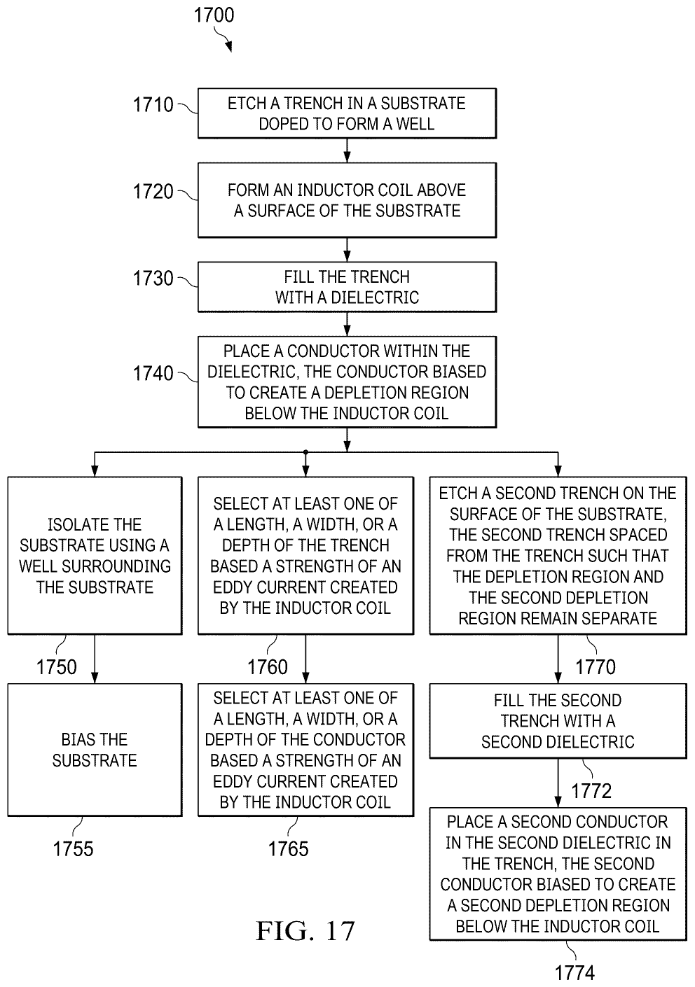

FIG. 17 illustrates a more detailed method performed for manufacturing an inductor with depletion regions created using DTI, according to examples of the present disclosure. Method 1700 may be implemented using any suitable semiconductor manufacturing device designed to perform the functions disclosed herein or any other system operable to implement method 1700. Although examples have been described above, other variations and examples may be made from this disclosure without departing from the spirit and scope of these disclosed examples.

Method 1700 may begin at block 1710 where a trench may be etched in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The trench may have a depth on the order of 10s of μms. The trench may be etched using any suitable technique, such as DRIE.

At block 1720, an inductor coil may be formed above a surface of the substrate. The inductor coil may be formed of layered metal stacks arranged in a coil shape.

At block 1730, the trench may be filled with a dielectric. The dielectric may be formed of any suitable insulating material, such as an oxide (e.g., silicon dioxide) or a nitride (e.g., silicon nitride). The dielectric may be filled in the trench using any suitable technique, such as CVD or PECVD.

At block 1740, a conductor may be placed with in the dielectric in the trench. The conductor may be formed of any suitable conductive material, such as polysilicon or metal (e.g., aluminum or copper). The conductor may be filled in the dielectric in the trench using any suitable technique, such as CVD or PECVD. The conductor in the trench may be biased to create a depletion region below the inductor coil.

At block 1750, the substrate may be isolated using a well surrounding the substrate. The substrate may be isolated to allow for biasing of the well (either P-well or N-well) formed by the substrate. The substrate may be isolated by surrounding the substrate with wells and a buried layer. Wells and the buried layer may have an opposite bias as the substrate. Specifically, where the substrate is a P-well, the well may be an N-well and the buried layer may be an N-buried layer. Likewise, where the substrate is a N-well, the well may be a P-well and the buried layer may be a P-buried layer.

At block 1755, the substrate may be biased. The substrate may be a P-well or an N-well.

At block 1760, at least one of a length, a width, or a depth of the trench may be selected based on an eddy current created by the inductor coil. At block 1765, at least one of a length, a width, or a depth of the conductor may be selected based on an eddy current created by the inductor coil. The selection may be based on the intended application of the inductor coil. The selection may also be based on optimizing the quality factor of the inductor coil.

At block 1770, a second trench may be etched in a substrate doped to form a well. The substrate may form either a P-well or an N-well. The substrate may be any suitable substrate, such as a silicon, silicon on insulator (SOI), gallium arsenide (GaAs), gallium nitride (GaN), silicon carbide (SiC), germanium, indium phosphide (InP), sapphire, or any combination thereof. In some examples, the substrate may be layered on an insulator layered on a silicon base. The second trench may have a depth on the order of 10s of μms. The second trench may be etched using any suitable technique, such as DRIE. The second trench may be substantially parallel to the trench. The second trench may be spaced from the trench such that the depletion region and a second depletion region created by the second trench remain separate. The spacing between the trench and the second trench may be based on a strength of an eddy current created by the inductor coil.

At block 1772, the second trench may be filled with a second dielectric. The second dielectric may be formed of any suitable insulating material, such as an oxide (e.g., silicon dioxide) or a nitride (e.g., silicon nitride). The second dielectric may be filled in the second trench using any suitable technique, such as CVD or PECVD.

At block 1774, a second conductor may be placed with in the second dielectric in the second trench. The second conductor may be formed of any suitable conductive material, such as polysilicon or metal (e.g., aluminum or copper). The second conductor may be filled in the second dielectric in the second trench using any suitable technique, such as CVD or PECVD. The second conductor in the second trench may be biased to create a second depletion region below the inductor coil.

Although FIG. 17 discloses a particular number of operations related to method 1700, method 1700 may be executed with greater or fewer operations than those depicted in FIG. 17. In addition, although FIG. 17 discloses a certain order of operations to be taken with respect to method 1700, the operations comprising method 1700 may be completed in any suitable order.

Although examples have been described above, other variations and examples may be made from this disclosure without departing from the spirit and scope of these disclosed examples.

1. An apparatus, comprising:
a substrate doped to form a well;
a trench etched in the substrate, the trench having a shape of a coil;
a dielectric in the trench; and
a conductor within the dielectric in the trench;
wherein the dielectric and the conductor create a first inductor.

2. The apparatus of claim 1, wherein the conductor is at least one of a polysilicon or a metal.

3. The apparatus of claim 1, comprising:
an inductor coil vertically stacked above a surface of the substrate; and
wherein the first inductor is tied to the inductor coil to form a combined inductor.

4. The apparatus of claim 1, comprising:
an inductor coil vertically stacked above a surface of the substrate and forming a second inductor; and
wherein the second inductor is a primary coil of a transformer and the first inductor is a secondary coil of the transformer.

5. The apparatus of claim 1, comprising:
a capacitor vertically stacked above a surface of the substrate; and
a conductive layer between the surface of the substrate and the capacitor.

6. The apparatus of claim 5, wherein the capacitor is a finger metal-oxide-metal (FMOM) capacitor or a metal-insulator-metal (MIM) capacitor.

7. The apparatus of claim 1, comprising:
a silicon base; and
an insulator layered on the silicon base;
wherein the substrate is layered on the insulator.

8. A method, comprising:
etching a trench in a substrate, the trench having a coil shape and the substrate doped to form a well;
filling the trench with a dielectric; and
placing a conductor within the dielectric;
wherein the dielectric and the conductor create a first inductor.

9. The method of claim 8, wherein the conductor is at least one of a polysilicon or a metal.

10. The method of claim 8, comprising:
stacking an inductor coil vertically above a surface of the substrate; and
wherein the first inductor is tied to the inductor coil to form a combined inductor.

11. The method of claim 8, comprising:
stacking an inductor coil vertically above a surface of the substrate to form a second inductor; and
wherein the second inductor is a primary coil of a transformer and the first inductor is a secondary coil of the transformer.

12. The method of claim 8, comprising:
stacking a capacitor vertically above a surface of the substrate; and
placing a conductive layer between the surface of the substrate and the capacitor.

13. The method of claim 12, wherein the capacitor is a finger metal-oxide-metal (FMOM) capacitor or a metal-insulator-metal (MIM) capacitor.

14. The method of claim 8, wherein:
layering the substrate on an insulator; and
layering the insulator on a silicon base.

15. An inductor made by a process comprising:
etching a trench in a substrate, the trench having a coil shape and the substrate doped to form a well;
filling the trench with a dielectric; and
placing a conductor within the dielectric;
wherein the dielectric and the conductor create a first inductor.

16. The inductor of claim 15, wherein the conductor is at least one of a polysilicon or a metal.

17. The inductor of claim 15, the process comprising:
stacking an inductor coil vertically above a surface of the substrate; and
wherein the first inductor is tied to the inductor coil to form a combined inductor.

18. The inductor of claim 15, the process comprising:
stacking an inductor coil vertically above a surface of the substrate to form a second inductor; and
wherein the second inductor is a primary coil of a transformer and the first inductor is a secondary coil of the transformer.

19. The inductor of claim 15, the process comprising:
stacking a capacitor vertically above a surface of the substrate; and
placing a conductive layer between the surface of the substrate and the capacitor.

20. The inductor of claim 19, wherein the capacitor is a finger metal-oxide-metal (FMOM) capacitor or a metal-insulator-metal (MIM) capacitor.
